(19) United States
(12) Patent Application Publication
(10) Pub. No.: US 2004/0110384 A1
(43) Pub. Date: Jun. 10, 2004

(54) Detecting method for dry etching machine

(76) Inventor: SZETSEN STEVEN LEE, HSINCHU (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,836

(22) Filed: Aug. 21, 2003

(30) Foreign Application Priority Data
Dec. 6, 2002 (TW) 91135493

(51) Int. Cl. H01L 21/302; H01L 21/461

(52) U.S. Cl. 438/706

(57) ABSTRACT

A detecting method for the dry etching machine under the semiconductor process is introduced. A certain number of wafers are sequentially performed with a dry etching process, wherein the Vpp value of each wafer under the etching process is recorded. Next, the Vpp values are processed by a mathematical algorithm, for eliminating some unreasonable values. Then, a Vpp range under the normal operation condition is obtained, based one the prediction from the mathematical algorithm, and is sent to the control system of the dry etching machine. The Vpp value of the wafer is compared to the Vpp range. If the Vpp value is within the Vpp range then it indicates a normal operation. If the Vpp value is out of the Vpp range, then the control system of the etching machine automatically stops the machine and issues a warning signal by voice or by E-mail or pager, so as to inform the operator to adjust the fabrication parameters for dry etching machine.

### CROSS REFERENCE TO RELATED APPLICATIONS

This application claims the priority benefit of Taiwan application No. 91135493, filed on Dec. 6, 2002.

### BACKGROUND OF INVENTION

1. Field of Invention

The present invention relates to a detecting method for a dry etching machine in semiconductor fabrication. More particularly, the present invention relates to a method capable of comparing the a Vpp value of wafer during the dry etching process in real-time to check whether or not the Vpp value is located within a Vpp range during a normal operation, so as to ensure an yield under the dry etching machine.

2. Description of Related Art

During fabrication of a semiconductor device, it usually needs several processes to accomplish, such as photolithography, etching, deposition, planarization, and so on. If a malfunction occurs on any one of these fabrication processes, and the malfunction is not found in time, the whole batch of semimanufactures with defects is still being fabricated for the subsequent processes to the last process. The defect is not found until the yield analysis on the accomplished product. In this situation, the only thing can do is scrapping those batches, which may have been tested, in a large amount. It is necessary to reexamine the fabrication process to find out which processes are in malfunction. This definitely causes a large amount of fabrication cost.

After 1980, when the pattern dimension in fabrication is reduced less than 3 microns, plasma etching (dry etching) gradually replaces the wet etching and is widely used in patterning process. This is because the wet etching is isotropic etching, causing that the pattern profile cannot be reduced to that small geometrical dimension, required by the fabrication. During the dry etching process, a large amount of heat is produced due to bombardment by the ions. If the wafer is not properly cooled down, the temperature on the wafer then rises. For example during etching in the patterning process, the wafer has been coated with a photoresist layer, serving as a mask layer. If the temperature of the wafer is over the 150° C., the mask layer will get scorched. In addition, the chemical etching rate is also sensitive to the wafer temperature. As shown in FIG. 1, the etching reaction chamber 100 is necessary to be implemented with the chilling platform, to prevent the mesh structure from occurring on the photoresist as well as control temperature of the wafer 104 and the etching rate of the plasma 108. Since the etching process is necessary to be performed at a low pressure, the low-pressure environment is adverse for heat conduction. In this manner, it is usually necessary to use the pressurized helium gas 102 at the backside of the wafer to conduct the heat energy from the wafer 104 to the chilling platform. In order to prevent the wafer from being blown away by the backside air stream at the chilling platform, it needs an electrostatic chuck (E-chuck) 106 to affix the wafer on the chilling platform by the electrostatic force. The E-chuck 106 is more popular in 1990 decade since it can provide the better uniformity of temperature and etching on the wafer, and have less polluting particles.

The dry etching is almost a standard process for the device to form the contact hole, deep trench, or shallow trench. During the etching process, if any malfunction, such as the poor quality of the E-chuck or the unstable air flow of the etching gas, can be found in time, the operator then can stop the etching process. This can save the cost for the subsequent processes. However, the response signal caused by the foregoing malfunction, such as pressure or temperature, is usually too small, and cannot be effectively detected out during the etching process. For example, since the pad layer, being thermal conductive but electrical insulating, on the E-chuck (ESC) is broken, the internal gas pipe for transferring the helium gas is then broken. Even though the helium gas for chilling the wafer does leak, the pressure variation in the chamber is still small and cannot be detected by the pressure sensor. In addition, the manufacturer of etching machine usually cannot provide sufficient detecting parameters to detect the actual operation condition during the etching process. The user cannot stop the etching machine in time for preventing the abnormal condition from being still going. In this consideration, if another parameter to observe the etching status can be supplied when the wafer is performed with the dry etching process, it would be very helpful to prevent those disadvantages.

### SUMMARY OF INVENTION

As discussed above about the conventional technology, the conventional etching machine cannot supply sufficient detecting parameters to detect the actual etching operation, and then the user cannot stop the operation of etching machine in time for preventing various abnormal operation from continuously going. The invention provides a method for detecting the dry etching machine during the semiconductor fabrication process. When the wafer is performed with the dry etching process, a wafer Vpp value for the period of dry etching process is compared with a Vpp range in the normal operation, so that the wafer yield can be ensured.

An objective of the invention is to provide a method for detecting the dry etching machine, so as to in-situ detect a status of the dry etching machine and prevent the abnormal fabrication process from continuously occurring.

As embodied and broadly described herein, the invention provides a method for detecting the dry etching machine, including etching a number of wafers with recoding the Vpp values for each of the wafer during the etching process in sequence. A Vpp range under the normal operation condition is obtained, according to the Vpp values. The Vpp range under the normal operation is sent to the control system of the dry etching machine. The Vpp value of the wafer is compared with the Vpp range to check whether or not the Vpp value is out of the Vpp range. If it is, then the control system of the etching machine enters the abnormal operation mode.

According to the forgoing aspect, wherein the number of wafers is equal to or greater than 200.

According to the forgoing aspect, when the etching machine enters the abnormal operation mode, the control system issues a warning signal.

According to the forgoing aspect, when the Vpp value is out of the Vpp range under normal operation, the abnormal operation is caused by the pad layer, being thermal conductive but electrical insulating, on the E-chuck (ESC) being broken.

According to the forgoing aspect, when the Vpp value is out of the Vpp range under normal operation, the abnormal operation is due to helium leakage, which is used to cool the wafers, caused by breakage of the transport pipe of internal helium in the E-chuck (ESC).

According to the forgoing aspect, when the Vpp value is out of the Vpp range under normal operation, the abnormal operation is caused by over temperature on the bottom of the etched wafer.

According to the forgoing aspect, when the Vpp value is out of the Vpp range under normal operation, the abnormal operation is caused by insufficient performance of a chilling system.

According to the forgoing aspect, when the Vpp value is out of the Vpp range under normal operation, the abnormal operation is caused by the abnormal oxygen flowing rate.

According to the forgoing aspect, when the Vpp value is out of the Vpp range under normal operation, the abnormal operation is due to a defect of the etched wafer itself.

According to the forgoing aspect, the dry etching machine is used in a deep trench process for dynamic random access memory (DT-DRAM).

According to the forgoing aspect, the deep trench process uses the reaction ion etching process (DT-RIE).

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating a dry etching reaction chamber.

FIG. 2A is a drawing, schematically illustrating a dry etching reaction chamber in capacitively coupled type.

FIG. 2B is a drawing, schematically illustrating a variation of the plasma potential with the time for the dry etching machine.

FIG. 3 is a drawing, schematically illustrating the curves of Vpp values and the final product yield (Y%) after performing the DT-RIE process on the wafer (about 200 wafers), wherein the sequence is in the order of the yield.

FIG. 4 is a drawing, schematically the curves of Vpp values and the final product yield, according to the data in FIG. 3 under the DT-RIE process, but rearranged in fabrication time sequence.

FIGS. 5A-5B are drawings, schematically illustrating the curves of Vpp value under the same DT-RIE process but in different etching machine in the fabrication time sequence.

FIG. 6 is a drawing, schematically illustrating a relation between the Vpp value and the stability of oxygen flow rate on the wafer during the dry etching process.

FIG. 7 is a drawing, schematically the flow chart of the detecting method on the dry etching machine, according to the present invention.

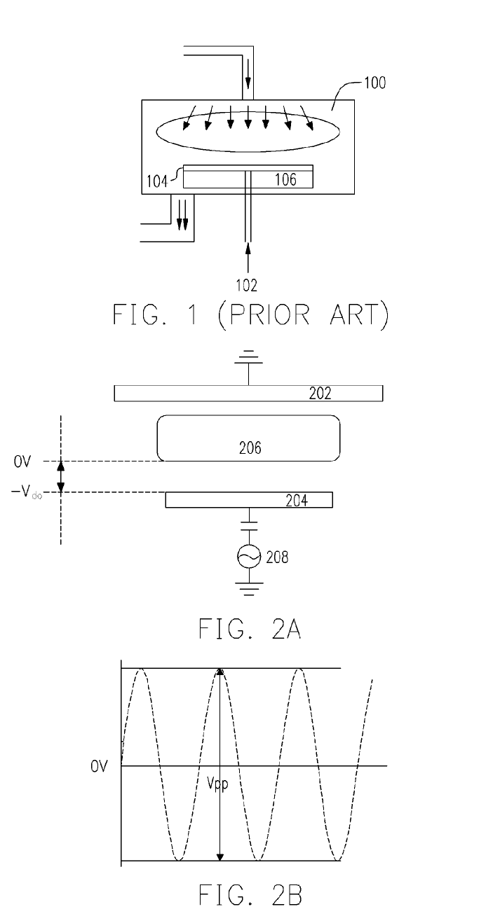

### DETAILED DESCRIPTION

The embodiment of the invention is described as follows. However, the invention can have other applications without limited to the embodiment. The scope is defined in claims.

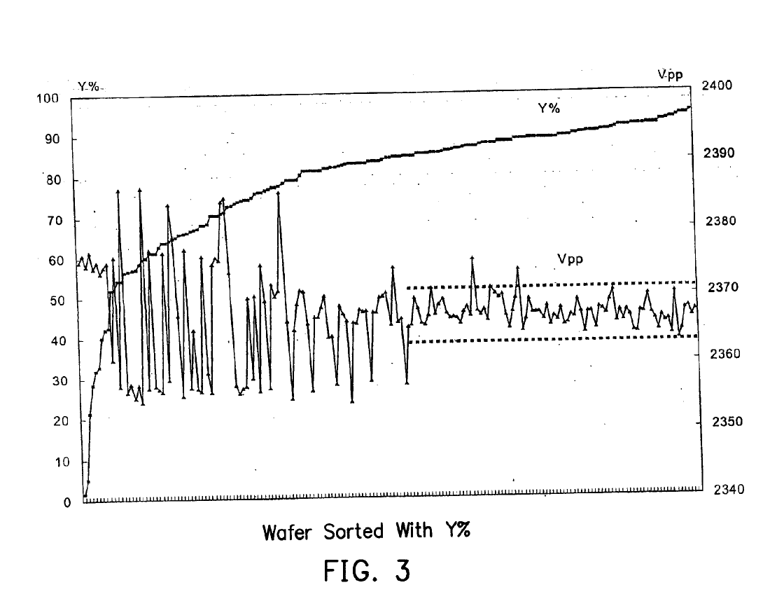

By using the detecting method for the dry etching machine of the invention, the occurrence of abnormal operation can be detected out in the beginning stage during dry etching process on the wafer. First, a reaction chamber in the etching process is considered as a large electric capacitor, as shown in FIG. 2A, and it is also called the capacitively coupled type. In the etching reaction chamber, a RF voltage is implemented between two parallel electrode plates 202, 204, for producing a large amount of plasma 206, wherein the RF plasma source 208 provides a RF potential. Since the potential of the plasma is higher than this RF potential and should remain to a state with higher potential than the ground, a DC voltage difference remains between the plasma (0V) 206 and the electrode (−Vdc) 204, which is also called DC bias. The etching capability of the plasma is determined by the DC bias. FIG. 2B is a drawing, schematically illustrating a variation of the plasma potential with the time for the dry etching machine. In FIG. 2B, the value from the peak (maximum) to the trough (minimum) of the plasma potential is defined as a Vpp value. It should be noted that, the Vpp value being used here is with respect to the plasma potential in stable state. It also means that the Vpp value for the transient state at the beginning stage of the etching process has been eliminated.

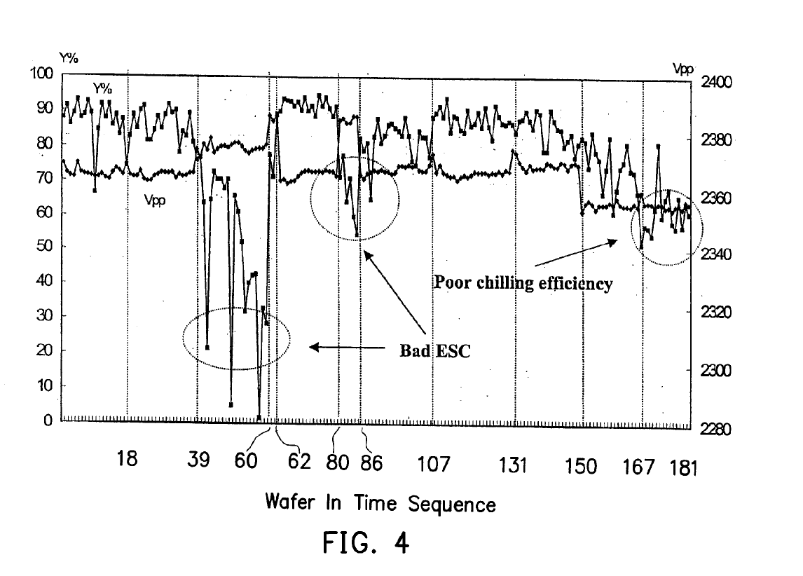

The process to fabricate the deep trench (DT) in dynamic random access memory (DRAM), that is, DT-DRAM process is used as the example for descriptions. During the DT-DRAM process, a reaction ion etching (RIE) process is used to form the DT, that is, DT-RIE Process, which is the essential process to determine the yield for the final products because the DT is used to form the capacitor for the DRAM. When the Vpp value for each wafer is observed during the DT-RIE process, it would be found that any abnormal operation from the wafer itself, or the equipment or the process in the RIE chamber, the Vpp value is obviously changed. FIG. 3 is a drawing, schematically illustrating the curves of Vpp values and the final product yield (Y%) after performing the DT-RIE process on the wafer (about 200 wafers), wherein the sequence is in the order of the yield. In FIG. 3, X axis is the serial number of the wafers but sorted in yield from low to high, the first Y axis is the yield, and the second Y axis is the Vpp value. It should be noted that the wafers have been sorted from small one to large one. In FIG. 3, when the yield is greater than 85%, the Vpp value for the DT-RIE process can remain in a Vpp range of 2363 2370, shown by dashed line. For the final products with the yield in 70%-85%, most of the wafers in the DT-RIE process have the Vpp values also within the above range. For the final products with the yield in 0%-70%, almost all of the wafers in the DT-RIE process have the Vpp values out of the Vpp range. According to this drawing, it indicates that when the wafers is performed with the DT-RIE process, the yield of final product on the wafer has the obvious tendency to be low if the VPP value is out of the Vpp range (overlarge or oversmall).

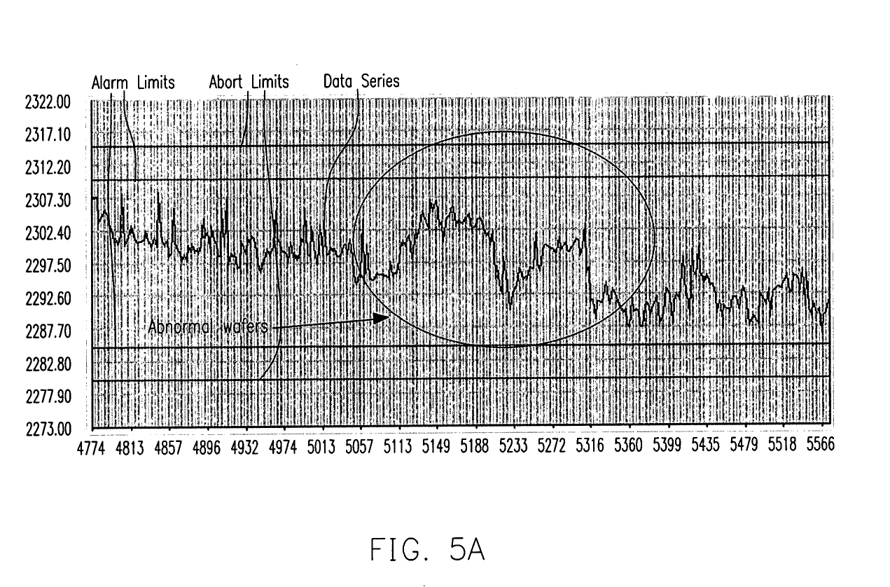

FIG. 4 is a drawing, schematically the curves of Vpp values and the final product yield, according to the data in FIG. 3 under the DT-RIE process, but rearranged in fabrication time sequence in X-axis. In FIG. 4, when the fabrication process proceeds to the first region, the product yield begins to drop from 80%, and this is also the rising point for the Vpp values. The subsequent few batches of wafers have not only low yield but also large variation. In this region, the Vpp values is larger than the Vpp values in the beginning stages of the etching machine. After the Vpp values return back to the beginning range, the yield rises up to about 90% again. The similar tendency occurs at the region B again. The Vpp values abnormally jump up, and the yield of the corresponding wafers then drop. The low yield for these two abnormal operations can be caused by the occurrence of abnormal state for the E-chuck (ESC) in etching reaction chamber. In addition, after the Vpp values in the region C drop out of the normal Vpp range, the yields obviously drop and have a large variation occurs. The reason can be understood due to poor chilling efficiency. The drawing again indicates that when the wafer is under the DT-RIE process, an abnormal condition for the machine equipment or fabrication parameter occurs if the Vpp values the out of a range (overlarge or oversmall).

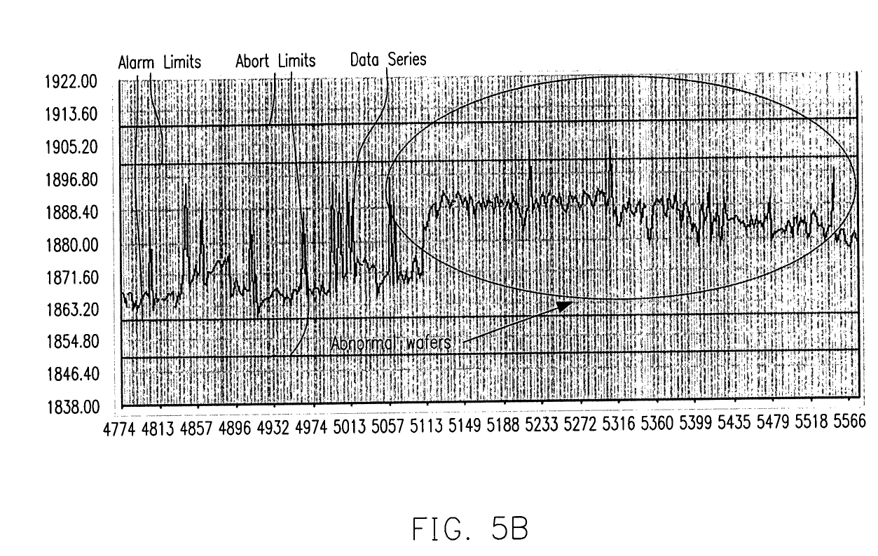

FIGS. 5A-5B are drawings, schematically illustrating the curves of Vpp value under the same DT-RIE process but in different etching machine in the fabrication time sequence. This situation is about performing the DT-RIE process in different etching machine, wherein the normal Vpp ranges for different machine may also different. In FIG. 5A, the normal Vpp range at the beginning stage is 2297 2307. In FIG. 5B, the normal Vpp range at the beginning stage is 1863 1880. The Vpp range is necessary to be set with respect to the different machine and one Vpp range cannot be used for all machines. Moreover, it can be seen as indicated by arrows in FIGS. 5A-5B when the Vpp value has the behavior different from the beginning stage set with the normal Vpp range, it indicates an abnormal phenomenon occurs on the etching machine.

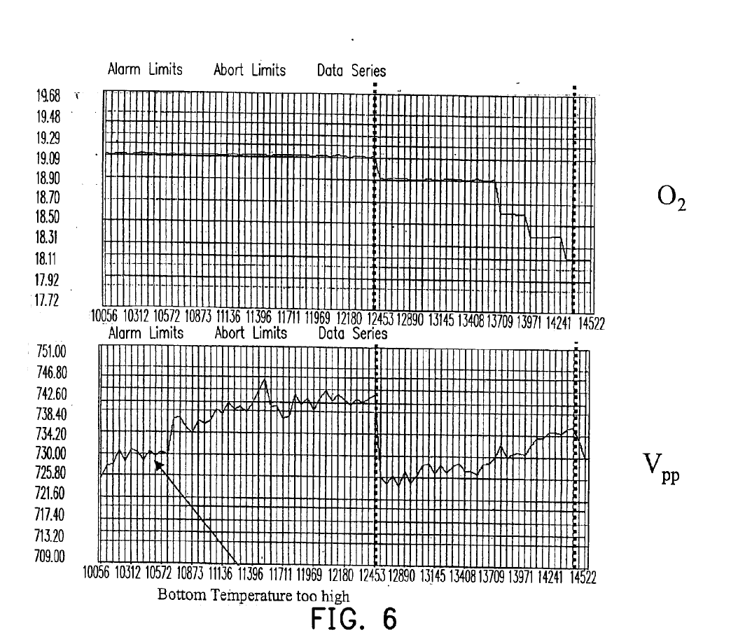

FIG. 6 is a drawing, schematically illustrating a relation between the Vpp value and the stability of oxygen flow rate on the wafer during the dry etching process. In FIG. 6, in two regions indicated by dashed lines, the oxygen flow rate is not stable during the etching process. The upper drawing shows the value drops from 19.09 to 18.21. The lower drawing shows that the corresponding Vpp values greatly drops from 742 to 725.8 when the oxygen flow rate starts dropping. Further still, in FIG. 6, it can be seen that the Vpp value has been abnormally low at the beginning stage, however, the oxygen flow rate is at the stable range. This can be understood that the result is caused by the over-high bottom temperature of the etched wafer (poor chilling performance). Again, the drawing can indicate whether or not the abnormal status occurs, such as low oxygen flow rate, over-high bottom temperature of the etched wafer, or poor chilling efficiency.

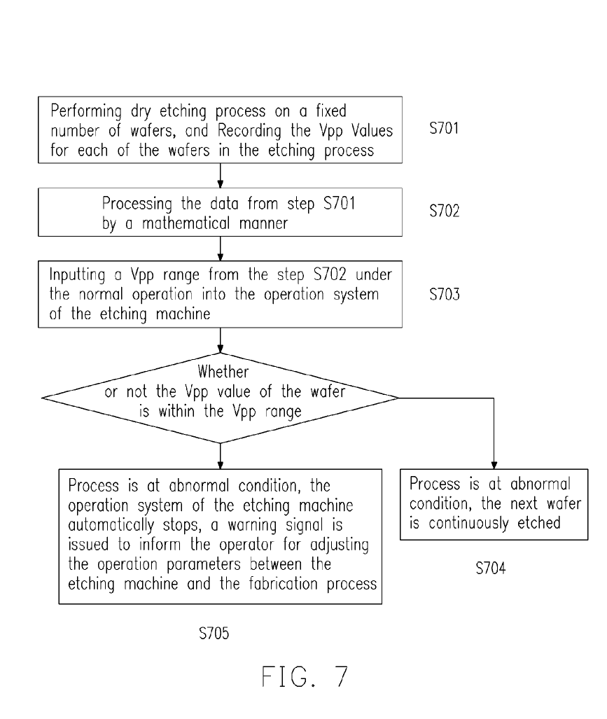

As foregoing descriptions, each etching machine has the individual Vpp range. Then, the detecting method of the invention is necessary to obtain the Vpp range under the normal operation for each etching machine for judging whether or not the operation is operated under the normal condition. FIG. 7 is a drawing, schematically the flow chart of the detecting method on the dry etching machine, according to the present invention. First, in step S701, a certain number of wafers are sequentially performed with etching process, wherein the Vpp values for each of the wafers are recorded and are used for determine a Vpp range under the normal operation. The number of wafers can be 200 or more. Then, In step S702, a mathematical analyzing algorithm is used to process the data from the step S701, so as to eliminate some effects due to the unreasonable large variations. Actually, this step can be skipped. However, the Vpp range may be affected a little. In step S703, the Vpp range obtained form the step S702 is input to the control system of he etching machine and is compared with the Vpp value for the subsequent dry etching process. If the Vpp value is within the Vpp range, then it indicates that the process is under the normal condition, in step S704. In step S705, if Vpp value is out of the Vpp range, then the control system of the etching machine stops the machine and issues a warning signal to inform the operator for adjusting the etching machine or the fabrication parameters. For example, it is checked whether or not the pad layer, with thermal conducting but electrical insulation, is broken in the E-chuck, causing the transporting pipe for the internal helium gas being broken, and the helium for cooling the wafer being leaking. It is checked whether or not the bottom temperature of the etched wafer is over high, the cooling system is in poor performance, or the oxygen flow rate is over low. As a result, the abnormal status can be prevented form occurring, and the yield can remain high.

According to the foregoing steps, the detecting method for the dry etching in the invention allows each of the etched wafers can be judged in real-time whether or not the abnormal operation occurs. This can solve the conventional disadvantage, which has insufficient detecting parameters to detecting etching operations, and the user cannot stop the etching machine in time for preventing the continuous abnormal operation.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A detecting method for a dry etching machine, comprising:
perform an etching process on a preset number of wafers, wherein Vpp values with respect to the wafers are recorded in the etching process;
obtaining a Vpp range under a working condition, according to the Vpp values of the wafers;
feeding the Vpp range to a control system of the dry etching machine; and
comparing Vpp values for a subsequent wafer under the etching process, wherein when the Vpp values are out of the Vpp range, then the control system of the dry etching machine enters an abnormal operation mode.

2. The method according to claim 1, wherein the preset number of the wafers is equal to or greater than 200.

3. The method according to claim 1, wherein the Vpp range is determined according to a mathematical analyzing algorithm.

4. The method according to claim 1, wherein when the etching machine enters the abnormal operation mode, the control system stops the etching machine.

5. The method according to claim 1, wherein when the etching machine enters the abnormal operation mode, the control system issues a warning signal.

6. The method according to claim 1, wherein a situation that the Vpp values are out of the Vpp range is caused by the pad layer, with thermal conducting but electrical insulation, on an E-chuck (ESC) being broken.

7. The method according to claim 1, wherein a situation that the Vpp values are out of the Vpp range is due to helium leakage, which is used to chill the wafers, caused by breakage of the transport pipe of internal helium gas in the E-chuck (ESC).

8. The method according to claim 1, wherein a situation that the Vpp values are out of the Vpp range is due to over temperature on the bottom of the etched wafer.

9. The method according to claim 1, wherein a situation that the Vpp values are out of the Vpp range is caused by insufficient performance of a chilling system.

10. The method according to claim 1, wherein a situation that the Vpp values are out of the Vpp range is caused by the abnormal oxygen flowing rate.

11. The method according to claim 1, wherein a situation that the Vpp values are out of the Vpp range is caused by a defect of the etched wafer itself.

12. The method according to claim 1, wherein the dry etching machine is used in a deep trench process for dynamic random access memory (DT-DRAM).

13. The method according to claim 12, wherein the deep trench process uses a reaction ion etching process (DT-RIE).
